(19) United States
(12) Patent Application Publication
(10) Pub. No.: US 2005/0215036 A1
(43) Pub. Date: Sep. 29, 2005

(54) Method for forming a doping superlattice using a laser

(76) Inventor: Nathan David Hiller, Fallbrook, CA (US)

Correspondence Address: Nathan David Hiller, 1323 Banyan Drive, Fallbrook, CA, 92028, US

(21) Appl. No.: 11/078,719

(22) Filed: Mar. 10, 2005

Related U.S. Application Data
(63) Continuation-in-part of application No. 10/810,450, filed on Mar. 26, 2004, now abandoned.

(51) Int. Cl. H01L 29/06; H01L 31/0328; H01L 31/0336; H01L 31/072; H01L 31/109; H01L 21/26; H01L 21/42

(52) U.S. Cl. 438/535

(57) ABSTRACT

A method for forming a doping superlattice using a laser is disclosed. By interfering a laser beam A (44a) and a laser beam B (44b) in a uniformly doped semiconductor or uniformly doped insulator (21), the uniformly doped semiconductor or uniformly doped insulator (21) is converted into a doping superlattice composed of dopant layers orientated parallel to the semiconductor's polished surface (57) or a doping superlattice composed of dopant layers orientated perpendicular to the semiconductor's polished surface (58). Using more complex laser beam interference patterns the uniformly doped semiconductor or uniformly doped insulator (21) can be converted into a doping superlattice composed of a two-dimensional array of dopant lines or dopant wires (108) or a doping superlattice composed of a three-dimensional array of dopant dots or dopant clusters (120).

### CROSS-REFERENCE TO RELATED APPLICATIONS

This patent application is a continuation-in-part application of U.S. patent application Ser. No. 10/810,450 filed Mar. 26, 2004.

### STATEMENT REGARDING FEDERALLY SPONSORED RESEARCH OR DEVELOPMENT

Not Applicable

### REFERENCE TO SEQUENCE LISTING, A TABLE, OR A COMPUTER PROGRAM LISTING COMPACT DISK APPENDIX

Not Applicable

### BACKGROUND OF THE INVENTION

This invention relates to methods for forming a doping superlattice, specifically to a doped semiconductor or doped insulator in which the dopant density in the doped semiconductor or doped insulator is a periodic function of position.

Doping superlattice is defined as a single phase, doped semiconductor or doped insulator in which the dopant density in the doped semiconductor or doped insulator is a periodic function of position in one, two, or three dimensional space. Single phase is defined as a mixture of components in which distinct boundaries between components do not exist. Dopant is defined as an impurity atom in a semiconductor or insulator that provides an electron to the conduction band or a hole to the valence band of the semiconductor or insulator under thermal excitation.

The unique electrical and optical properties of a doping superlattice could lead to variety of novel devices relating to photodetectors, tunable light sources, spatial light modulators, Bragg reflectors, optical amplifiers, all-optical switches, saturable absorbers, optical bistability, and nanophotonic crystals.

There are two types of prior art methods relevant to forming a doping superlattice. The first type of prior art method uses epitaxy methods to form a doping superlattice and will be referred to as the epitaxy prior art methods. The second type of prior art method uses laser beam interference to form a periodic structure and will be referred to as the laser prior art method.

The major problems with the epitaxy prior art methods used to form a doping superlattice is that each method uses a layer-by-layer approach, which by its nature is a slow process, requires expensive equipment, and is limited to forming a doping superlattice in which the dopant density is a periodic function of position in only one dimensional space, such as multiple layers. Furthermore, large-scale devices and components in which a doping superlattice is the enabling technology have not been developed because epitaxy prior art methods cannot produce monolithic size samples composed of a doping superlattice.

A semiconductor composed of a doping superlattice was first proposed by Esaki and Tsu in the IBM Journal of Research and Development, volume 14, page 61, 1970.

The first doping superlattice composed of dopant layers was fabricated by Ovsyannikov et al, and disclosed in Soviet Physics—Semiconductors, volume 4, no. 12, page 1919, 1970. The doping superlattice fabricated by Ovsyannikov et al, consisted of silicon. The dopant layer thickness' ranged from 200 nm to 1,000 nm and 30 periods were formed.

In 1981 a doping superlattice composed of dopant layers was fabricated using molecular beam epitaxy by Ploog et al, and disclosed in the Journal of the Electrochemical Society, volume 128, page 400, 1981. The doping superlattice fabricated by Ploog et al, consisted of GaAs where Be and Si were used as dopants. Each dopant layer was as thick as 100 nm and 10 periods were formed.

A doping superlattice composed of dopant layers was fabricated using hydride vapor phase epitaxy by Yamauchi et al, and disclosed in the Japanese Journal of Applied Physics, volume 23, number 10, page L785, 1984. The doping superlattice fabricated by Yamauchi et al, consisted of InP where Zn and S were used as dopants. The thickness of the dopant layers ranged from 15 nm to 200 nm.

A doping superlattice composed of dopant layers was fabricated using a modified hot-wall technique by Jantsch et al, and disclosed in the Applied Physics Letters, volume 47, number 7, page 738, 1985. The doping superlattice fabricated by Jantsch et al, consisted of PbTe where the dopant layer thickness' ranged from 93 nm to 135 nm.

A doping superlattice composed of dopant layers was fabricated using organometallic vapor-phase epitaxy by Kitamura et al, and disclosed in the Journal of Applied Physics, volume 61, number 4, page 1533, 1987. The doping superlattice fabricated by Kitamura et al, consisted of GaP where Te and Zn were used as dopants. Each dopant layer was 20 nm thick and 40 periods were formed.

The main problem with each of the epitaxy prior art methods used to fabricate a doping superlattice as described thus far is that the doping superlattice layers cannot be formed simultaneously because each layer provides the structural support for the follow on layer. Thus, only one layer can be formed at a time, which by nature is slow. To produce monolithic size samples composed of a doping superlattice using the epitaxy prior art methods requires long fabrication times and expensive equipment. Furthermore, the epitaxy prior art methods cannot form a doping superlattice in which the dopant density is a period function of position in more than one dimension, which is required for a two-dimensional array of dopant lines or dopant wires and a three-dimensional array of dopant dots or dopant clusters.

The major problem with the laser prior art method used to form a periodic structure is that the periodic structure formed is not a doping superlattice because it is composed of two phases. A periodic structure composed of layers of precipitated nanoparticles was fabricated using the interference pattern of a laser beam by Nishiyama et al, and disclosed in the Fifth International Symposium on Laser Precision Microfabrication, SPIE volume 5662, page 135, 2004. The periodic structure formed consisted of a Ge—B—SiO₂ thin glass film where Ge nanoparticles existed to form a layered periodic structure. The diameter of the Ge nanoparticles ranged from 20-40 nm and existed as a second phase in the Ge—B—SiO₂ glass. The Ge nanoparticle layers were approximately 200 nm thick. The problem with the laser prior art method used to form a periodic structure is that the periodic structure formed is not a doping superlattice because it is composed of two phases.

### BRIEF SUMMARY OF THE INVENTION

In accordance with the present invention a method for forming a doping superlattice using a laser. The doping superlattice formed is a doped semiconductor in which the dopant density in the semiconductor is a periodic function of position. Initially the dopant density in the semiconductor is uniformly distributed, then using a laser the uniform dopant distribution is rearranged into a distribution that is a periodic function of position.

Accordingly, several objects and advantages of my invention are:
a) to provide a method for forming a doping superlattice composed of dopant layers in a semiconductor or insulator where each dopant layer is formed simultaneously;
b) to provide a method for forming a doping superlattice composed of a two-dimensional array of dopant lines or dopant wires in a semiconductor or insulator where each dopant line or dopant wire is formed simultaneously;
c) to provide a method for forming a doping superlattice composed of a three-dimensional array of dopant dots or dopant clusters in a semiconductor or insulator where each dopant dot or dopant cluster is formed simultaneously;
d) to provide a method for forming a doping superlattice in a semiconductor or insulator where the doping superlattice period or spacing is constant.

Another object and advantage is to provide a method for forming a doping superlattice that is dynamic. Dynamic is defined as changeable during the use of or after using the doping superlattice. Still further objects and advantages of my invention will become apparent from a consideration of the ensuing description and drawings.

### BRIEF DESCRIPTION OF THE SEVERAL VIEWS OF THE DRAWING

In the drawings, closely related figures and parts have the same number but different alphabetical suffixes.

FIG. 1 shows a uniformly doped semiconductor or uniformly doped insulator.

FIGS. 2A to 2C show an optical setup and process for converting the uniformly doped semiconductor or uniformly doped insulator into a doping superlattice composed of dopant layers using a laser.

FIGS. 3A to 3C show an optical setup and process for converting the uniformly doped semiconductor or uniformly doped insulator into a doping superlattice composed of dopant layers using a laser, a beamsplitter, and two reflectors.

FIGS. 4A to 4C show an optical setup and process for converting the uniformly doped semiconductor or uniformly doped insulator into a doping superlattice composed of dopant layers using a laser, a beamsplitter, and one reflector.

FIG. 5 shows a doping superlattice composed of a two-dimensional array of dopant lines or dopant wires.

FIG. 6 shows a doping superlattice composed of a three-dimensional array of dopant dots or dopant clusters.

### REFERENCE NUMERALS IN DRAWINGS

20 semiconductor or insulator
21 uniformly doped semiconductor or uniformly doped insulator
22 dopant
26 laser source
28 beamsplitter
29a reflector A
29b reflector B
40a beam A direction of propagation
40b beam B direction of propagation
44a beam A
44b beam B
54 period of the laser beam interference pattern
56 distance between adjacent layers composed of a high dopant density
57 doping superlattice composed of dopant layers orientated parallel to the semiconductor's polished surface
58 doping superlattice composed of dopant layers orientated perpendicular to the semiconductor's polished surface
59 layer composed of a high dopant density
60 layer composed of a low dopant density
104 region composed of a low dopant density
106 line or wire composed of a high dopant density
108 doping superlattice composed of a two-dimensional array of dopant lines or dopant wires
110 dot or cluster composed of a high dopant density
120 doping superlattice composed of a three-dimensional array of dopant dots or dopant clusters

### DETAILED DESCRIPTION OF THE INVENTION

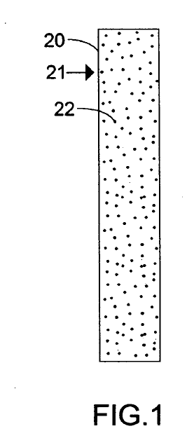

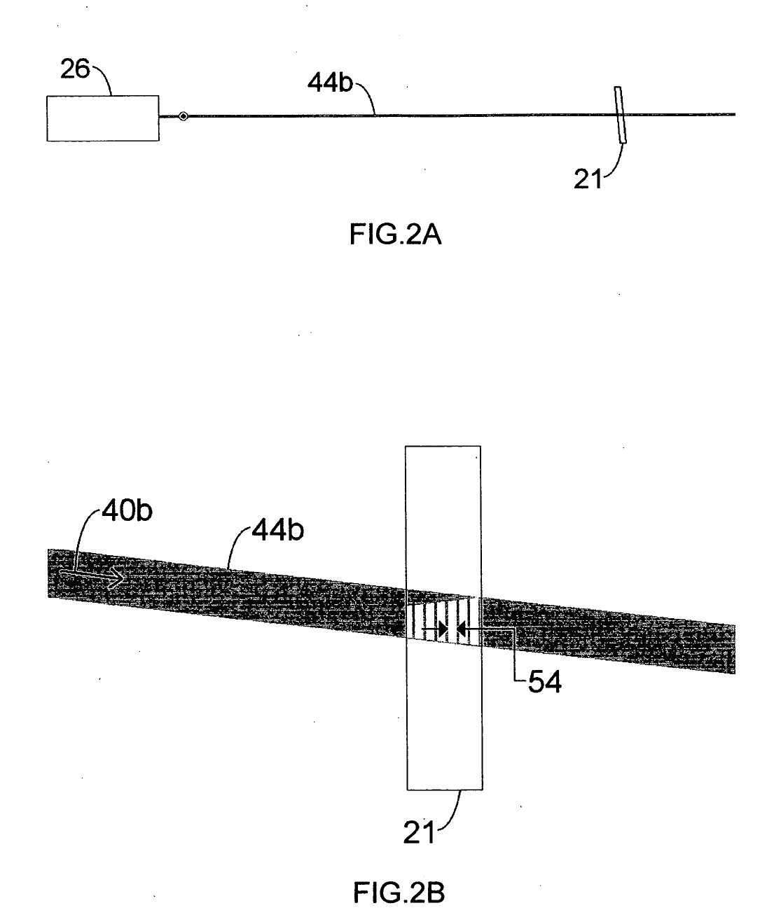

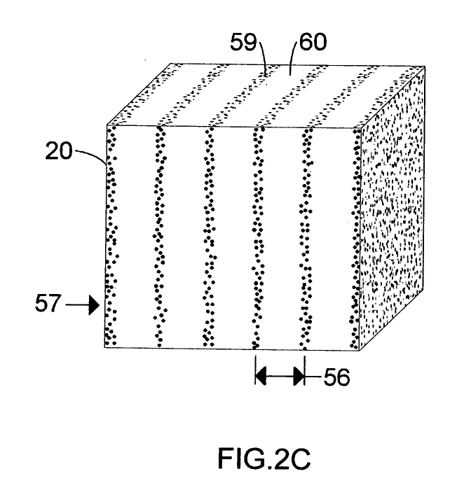

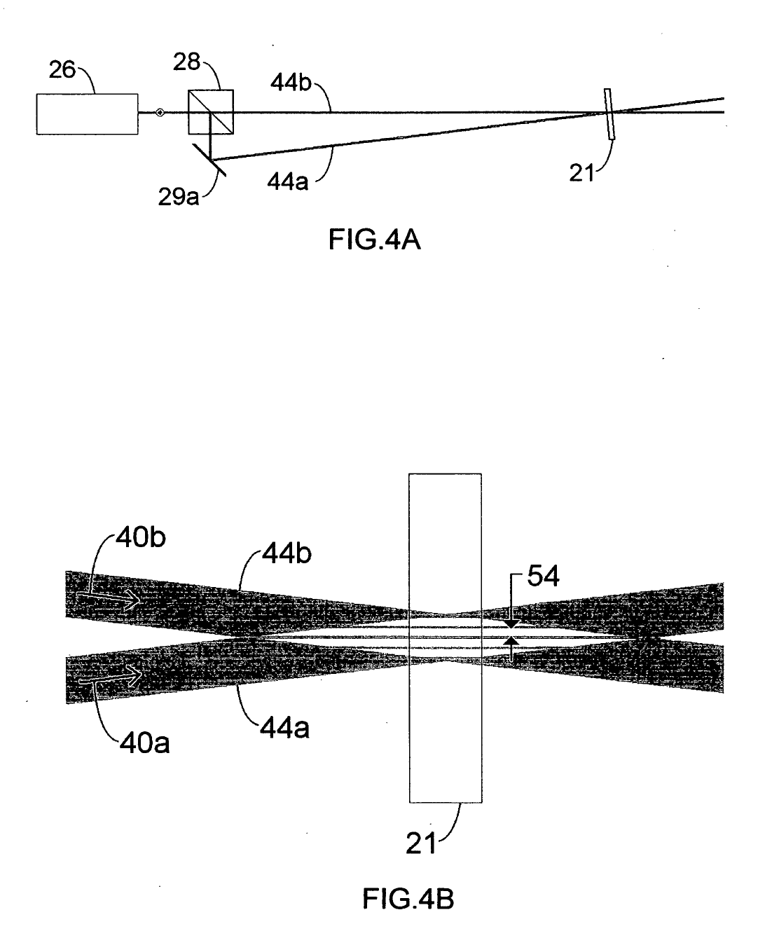

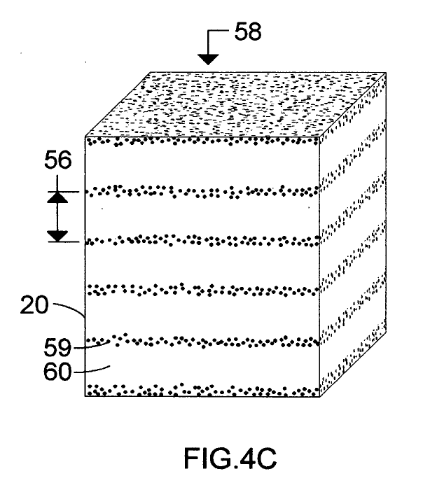

FIG. 1 shows a uniformly doped semiconductor or uniformly doped insulator 21 before it is converted into a doping superlattice composed of dopant layers orientated parallel to the semiconductor's polished surface 57 (FIG. 2C) or a doping superlattice composed of dopant layers orientated perpendicular to the semiconductor's polished surface 58 (FIG. 4C). To form the uniformly doped semiconductor or uniformly doped insulator 21 a semiconductor or insulator 20 is uniformly doped with a dopant 22 at a dopant density defined as the variable Z. The uniformly doped semiconductor or uniformly doped insulator 21 will be referred to as the uniformly doped semiconductor 21 for the remainder of this document. The semiconductor or insulator 20 will be referred to as the semiconductor 20 for the remainder of this document.

FIG. 2A shows an optical setup for converting the uniformly doped semiconductor 21 into the doping superlattice composed of dopant layers orientated parallel to the semiconductor's polished surface 57 (FIG. 2C) using a laser source 26. The laser source 26 emits a beam B 44b that propagates through the uniformly doped semiconductor 21.

FIG. 2B is an enlarged view of the FIG. 2A intersection of the uniformly doped semiconductor 21 and the beam B 44b (FIG. 2A). The dopant 22 exists in the uniformly doped semiconductor 21 but is not shown in FIG. 2B. The beam B 44b has a beam B direction of propagation 40b, which is indicated by an arrow. The surfaces in which the beam B 44b enters and exits the uniformly doped semiconductor 21 are polished and parallel to each other. A variable θ is defined as the angle between a line normal to the polished surface of the uniformly doped semiconductor 21 and the beam B direction of propagation 40b before it enters the uniformly doped semiconductor 21. A portion of the beam B 44b is reflected at the surface in which the beam B 44b exits the uniformly doped semiconductor 21. The overlap of the beam B 44b and the reflected portion of beam B 44b results in the formation of a laser beam interference pattern inside the uniformly doped semiconductor 21. A period of the laser beam interference pattern 54 exists for the laser beam interference pattern. The period of the laser beam interference pattern 54 is defined as the variable Λ. The value of Λ for the FIG. 2A configuration in air at 25° C. and 1 atm can be approximated using the equation: Λ=λ/[2n\sqrt{1−(1/n)² sin²(θ)}] where λ is the wavelength of the laser source 26 in a vacuum, and n is the index of refraction of the semiconductor 20 at λ. Hence, Λ can be controlled by changing λ, θ, or n. Over time the laser beam interference pattern forms the doping superlattice composed of dopant layers orientated parallel to the semiconductor's polished surface 57 (FIG. 2C). The variable tₚ is defined as the amount of time required for the laser beam interference pattern to form the doping superlattice composed of dopant layers orientated parallel to the semiconductor's polished surface 57 (FIG. 2C).

FIG. 2C is the FIG. 2B section of the uniformly doped semiconductor 21 in which the laser beam interference pattern existed within it for a time tₚ. The section of the uniformly doped semiconductor 21 in which the laser beam interference pattern existed within it for a time tₚ is the doping superlattice composed of dopant layers orientated parallel to the semiconductor's polished surface 57. A layer composed of a high dopant density 59 exists for regions of the semiconductor 20 containing a dopant density that is greater than the dopant density Z. A layer composed of a low dopant density 60 exists for regions of the semiconductor 20 containing a dopant density that is less than the dopant density Z. The layer composed of a high dopant density 59 and the layer composed of a low dopant density 60 are called dopant layers. A distance between adjacent layers composed of a high dopant density 56 exists and it is equal to Λ.

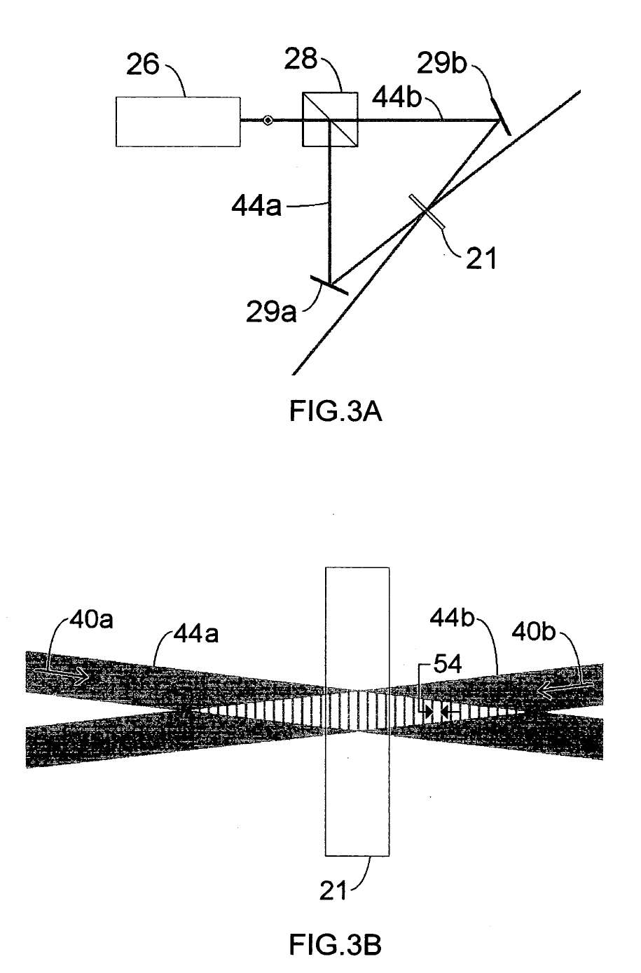

FIG. 3A shows another optical setup for converting the uniformly doped semiconductor 21 into the doping superlattice composed of dopant layers orientated parallel to the semiconductor's polished surface 57 (FIG. 2C) using the laser source 26. The laser source 26 emits a beam that is split into the beam B 44b and a beam A 44a using a beamsplitter 28. The beam A 44a is reflected from a reflector A 29a and the beam B 44b is reflected from a reflector B 29b such that the beam A 44a and the beam B 44b intersect. The ratio of the beam A 44a spot size area to the beam B 44b spot size area is not greater than 1.1 or less than 0.91 at the intersection of the beam A 44a and the beam B 44b. The ratio of the beam A 44a power to the beam B 44b power is not greater than 1.1 or less than 0.91 at the intersection of the beam A 44a and the beam B 44b. The center of the uniformly doped semiconductor 21 is located at the intersection of the beam A 44a and the beam B 44b.

FIG. 3B is an enlarged view of the FIG. 3A uniformly doped semiconductor 21 located at the intersection of the beam A 44a and the beam B 44b (FIG. 3A). The dopant 22 exists in the uniformly doped semiconductor 21 but is not shown in FIG. 3B. The beam A 44a has a beam A direction of propagation 40a, which is indicated by an arrow. The surfaces in which the beam B 44b and beam A 44a enters and exits the uniformly doped semiconductor 21 are polished and parallel to each other. The angle between a line normal to the polished surface of the uniformly doped semiconductor 21 and the beam B direction of propagation 40b before it enters the uniformly doped semiconductor 21 is defined as the variable θ and θ is equal to the angle between a line normal to the polished surface of the uniformly doped semiconductor 21 and the beam A direction of propagation 40a before it enters the uniformly doped semiconductor 21. The overlap of the beam B 44b and the beam A 44a results in the formation of a laser beam interference pattern inside the uniformly doped semiconductor 21. The period of the laser beam interference pattern 54 is equal to Λ for the FIG. 3A configuration in air at 25° C. and 1 atm. Over time the laser beam interference pattern forms the doping superlattice composed of dopant layers orientated parallel to the semiconductor's polished surface 57 (FIG. 2C). The variable tₚ is the amount of time required for the laser beam interference pattern to form the doping superlattice composed of dopant layers orientated parallel to the semiconductor's polished surface 57 (FIG. 2C).

FIG. 4A shows an optical setup for converting the uniformly doped semiconductor 21 into the doping superlattice composed of dopant layers orientated perpendicular to the semiconductor's polished surface 58 (FIG. 4C) using the laser source 26. The laser source 26 beam is split into the beam A 44a and the beam B 44b using the beamsplitter 28. The beam A 44a is reflected from a reflector A 29a such that the beam A 44a intersects the beam B 44b. The ratio of the beam A 44a spot size area to the beam B 44b spot size area is not greater than 1.1 or less than 0.91 at the intersection of the beam A 44a and the beam B 44b. The ratio of the beam A 44a power to the beam B 44b power is not greater than 1.1 or less than 0.91 at the intersection of the beam A 44a and the beam B 44b. The center of the uniformly doped semiconductor 21 is located at the intersection of the beam A 44a and the beam B 44b.

FIG. 4B is an enlarged view of the FIG. 4A uniformly doped semiconductor 21 located at the intersection of the beam A 44a and the beam B 44b. The dopant 22 exists in the uniformly doped semiconductor 21 but is not shown in FIG. 4B. The surfaces in which the beam B 44b and beam A 44a enters and exits the uniformly doped semiconductor 21 are polished and parallel to each other. The angle between a line normal to the polished surface of the uniformly doped semiconductor 21 and the beam B direction of propagation 40b before it enters the uniformly doped semiconductor 21 is θ and θ is equal to the angle between a line normal to the polished surface of the uniformly doped semiconductor 21 and the beam A direction of propagation 40a before it enters the uniformly doped semiconductor 21. The overlap of the beam B 44b and the beam A 44a results in the formation of a laser beam interference pattern inside the uniformly doped semiconductor 21. The period of the laser beam interference pattern 54 is defined as the variable ψ. The value of ψ for the FIG. 4A configuration in air at 25° C. and 1 atm can be approximated using the equation: ψ=λ/[2 sin(θ)]. Over time the laser beam interference pattern forms the doping superlattice composed of dopant layers orientated perpendicular to the semiconductor's polished surface 58 (FIG. 4C). The variable tₚ is the amount of time required for the laser beam interference pattern to form the doping superlattice composed of dopant layers orientated perpendicular to the semiconductor's polished surface 58 (FIG. 4C).

FIG. 4C is the FIG. 4B section of the uniformly doped semiconductor 21 in which the laser beam interference pattern existed within it for a time tₚ. The section of the uniformly doped semiconductor 21 in which the laser beam interference pattern existed within it for a time tₚ is the doping superlattice composed of dopant layers orientated perpendicular to the semiconductor's polished surface 58. The layer composed of a high dopant density 59 exists for regions of the semiconductor 20 containing a dopant density that is greater than the dopant density Z. The layer composed of a low dopant density 60 exists for regions of the semiconductor 20 containing a dopant density that is less than the dopant density Z. The distance between adjacent layers composed of a high dopant density 56 exists and it is equal to ψ.

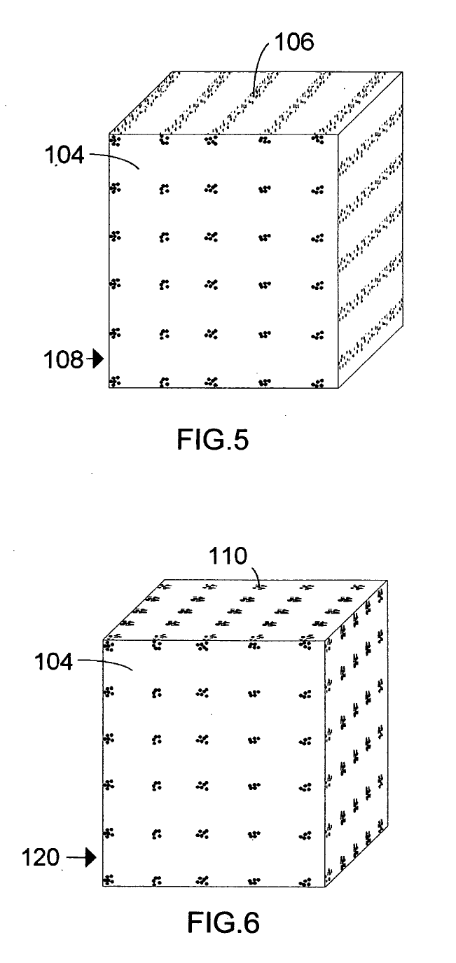

FIG. 5 is a doping superlattice composed of a two-dimensional array of dopant lines or dopant wires 108. The doping superlattice composed of a two-dimensional array of dopant lines or dopant wires 108 is composed of a region composed of a low dopant density 104 and a line or wire composed of a high dopant density 106. The line or wire composed of a high dopant density 106 exists for regions of the semiconductor 20 containing a dopant density that is greater than the dopant density Z. The region composed of a low dopant density 104 exists for regions in which the dopant density is less than the dopant density Z. The line or wire composed of a high dopant density 106 is called a dopant line or dopant wire. The doping superlattice composed of a two-dimensional array of dopant lines or dopant wires 108 is formed if two of the FIG. 2B, FIG. 3B, or FIG. 4B laser beam interference patterns are formed perpendicular to one another in the uniformly doped semiconductor 21. The uniformly doped semiconductor 21 can be cut into a cube to reduce the difficulty of forming two of the FIG. 2B, FIG. 3B, or FIG. 4B laser beam interference patterns perpendicular to one another in the uniformly doped semiconductor 21. There are numerous optical setups that can form two of the FIG. 2B, FIG. 3B, or FIG. 4B interference patterns perpendicular to one another in the uniformly doped semiconductor 21 through the use of additional beamsplitters and mirrors.

FIG. 6 is a doping superlattice composed of a three-dimensional array of dopant dots or dopant clusters 120. The doping superlattice composed of a three-dimensional array of dopant dots or dopant clusters 120 is composed of the region composed of a low dopant density 104 and a dot or cluster composed of a high dopant density 110. The dot or cluster composed of a high dopant density 110 exists for regions in which the dopant density is greater than the dopant density Z. The region composed of a low dopant density 104 exists for regions in which the dopant density is less than the dopant density Z. The dot or cluster composed of a high dopant density 110 is called a dopant dot or dopant cluster. The doping superlattice composed of a three-dimensional array of dopant dots or dopant clusters 120 is formed if three of the FIG. 2B, FIG. 3B, or FIG. 4B interference patterns are formed perpendicular to one another in the uniformly doped semiconductor 21. There are numerous optical setups that can form three of the FIG. 2B, FIG. 3B, or FIG. 4B interference patterns perpendicular to one another in the uniformly doped semiconductor 21 through the use of additional beamsplitters and mirrors.

Operation

Six examples in which the present invention is used to form a doping superlattice will be described in the following six paragraphs.

### EXAMPLE 1

For example 1 the optical configuration illustrated in FIG. 2A is used in air at 25° C. and 1 atm. Let the uniformly doped semiconductor 21 be a 1 mm thick, 10 mm diameter, polished wafer of single-crystalline wurtzite CdS where the c-axis is perpendicular to the wafer's polished surfaces. Let the uniformly doped semiconductor 21 have a front and back surface polish of 0.002 μm, a flatness of less than 15 μm, and a bow of less than 20 μm. Let the uniformly doped semiconductor 21 have an electron concentration of 2×10¹⁶ cm⁻³ in the conduction band at 25° C. Let the dopant 22 be Cu where Z=1×10¹⁵ Cu atoms/cm³. Let the laser source 26 be a constant wave, helium neon laser operating at 632.8 nm in the TEM₀₀ mode at a power output of 75 mW. Let the laser source 26 have a beam diameter and beam waste of 1.91 mm at the laser source 26 opening and a beam divergence of 0.00046 radians. The laser source 26 can be purchased from Jodon, Inc., 62 Enterprise Drive, Ann Arbor, Mich. 48103, using the part number 1508. The polarization of the beam B 44b is such that the direction of its electric field is perpendicular to the c-axis of the uniformly doped semiconductor 21. Let the distance between the laser source 26 and the uniformly doped semiconductor 21 be 1 m and let θ=5°. The temperature of the uniformly doped semiconductor 21 is 25° C.±5° C. If tₚ=24 hours then the doping superlattice composed of dopant layers orientated parallel to the semiconductor's polished surface 57 will be formed where Λ=129 nm±3 nm.

### EXAMPLE 2

For example 2 the optical configuration illustrated in FIG. 3A is used in air at 25° C. and 1 atm. Let the uniformly doped semiconductor 21 be a 1 mm thick, 10 mm diameter, polished wafer of single-crystalline wurtzite CdS where the c-axis is perpendicular to the wafer's polished surfaces. Let the uniformly doped semiconductor 21 have a front and back surface polish of 0.002 μm, a flatness of less than 15 μm, and a bow of less than 20 μm. Let the uniformly doped semiconductor 21 have an electron concentration of 2×10¹⁶ cm⁻³ in the conduction band at 25° C. Let the dopant 22 be Cu where Z=1×10¹⁵ Cu atoms/cm³. Let the laser source 26 be a constant wave, helium neon laser operating at 632.8 nm in the TEM₀₀ mode at a power output of 75 mW. Let the laser source 26 have a beam diameter and beam waste of 1.91 mm at the laser source 26 opening and a beam divergence of 0.00046 radians. The laser source 26 can be purchased from Jodon, Inc., 62 Enterprise Drive, Ann Arbor, Mich. 48103, using the part number 1508. The polarization of the beam B 44b is such that the direction of its electric field is perpendicular to the c-axis of the uniformly doped semiconductor 21. The polarization of the beam A 44a is such that the direction of its electric field is perpendicular to the c-axis of the uniformly doped semiconductor 21. Let the beam splitter 28 be a nonpolarizing cube beamsplitter designed for the laser wavelength 632.8 nm. Let the reflector A 29a and the reflector B 29b be square flat mirrors made from crown glass and coated with aluminum. The beam splitter 28, the reflector A 29a, and the reflector B 29b can be purchased from Melles Griot, 2051 Palomar Airport Road, 200, Carlsbad, Calif. 92009 using the part numbers 03 BSL 043 and 01 MFG 003. Let the distance between the laser source 26 and the beam splitter 28 be 1 m. Let the distance between the beam splitter 28 and the reflector B 29b be 1 m. Let the distance between the beam splitter 28 and the reflector A 29a be 1 m. Let θ=20°. The temperature of the uniformly doped semiconductor 21 is 25° C.±5° C. If tₚ=24 hours then the doping superlattice composed of dopant layers orientated parallel to the semiconductor's polished surface 57 will be formed where Λ=130 nm±3 nm.

### EXAMPLE 3

For example 3 the optical configuration illustrated in FIG. 4A is used in air at 25° C. and 1 atm. Let the uniformly doped semiconductor 21 be a 1 mm thick, 10 mm diameter, polished wafer of single-crystalline wurtzite CdS where the c-axis is perpendicular to the wafer's polished surfaces. Let the uniformly doped semiconductor 21 have a front and back surface polish of 0.002 μm, a flatness of less than 15 μm, and a bow of less than 20 μm. Let the uniformly doped semiconductor 21 have an electron concentration of 2×10¹⁶ cm⁻³ in the conduction band at 25° C. Let the dopant 22 be Cu where Z=1×10¹⁵ Cu atoms/cm³. Let the laser source 26 be a constant wave, helium neon laser operating at 632.8 nm in the TEM₀₀ mode at a power output of 75 mW. Let the laser source 26 have a beam diameter and beam waste of 1.91 mm at the laser source 26 opening and a beam divergence of 0.00046 radians. The laser source 26 can be purchased from Jodon, Inc., 62 Enterprise Drive, Ann Arbor, Mich. 48103, using the part number 1508. The polarization of the beam B 44b is such that the direction of its electric field is perpendicular to the c-axis of the uniformly doped semiconductor 21. The polarization of the beam A 44a is such that the direction of its electric field is perpendicular to the c-axis of the uniformly doped semiconductor 21. Let the beam splitter 28 be a nonpolarizing cube beamsplitter designed for the laser wavelength 632.8 nm. Let the reflector A 29a be square flat mirror made from crown glass and coated with aluminum. The beam splitter 28 and the reflector A 29a can be purchased from Melles Griot, 2051 Palomar Airport Road, 200, Carlsbad, Calif. 92009 using the part numbers 03 BSL 043 and 01 MFG 003. Let the distance between the laser source 26 and the beam splitter 28 be 1 m. Let the distance between the beam splitter 28 and the reflector A 29a be 10 cm. Let θ=2°. The temperature of the uniformly doped semiconductor 21 is 25° C.±5° C. If tₚ=24 hours then the doping superlattice composed of dopant layers orientated perpendicular to the semiconductor's polished surface 58 will be formed where ψ=9 μm±0.2 μm.

### EXAMPLE 4

For example 4 the optical configuration illustrated in FIG. 2A is used in air at 25° C. and 1 atm. Let the uniformly doped semiconductor 21 be a 1 mm thick, 10 mm diameter, polished wafer of single-crystalline wurtzite CdS where the c-axis is perpendicular to the wafer's polished surfaces. Let the uniformly doped semiconductor 21 have a front and back surface polish of 0.002 μm, a flatness of less than 15 μm, and a bow of less than 20 μm. Let the uniformly doped semiconductor 21 have an electron concentration of 2×10¹⁶ cm ⁻³ in the conduction band at 25° C. Let the dopant 22 be Ag where Z=1×10¹⁵ Ag atoms/cm³. Let the laser source 26 be a constant wave, helium neon laser operating at 632.8 nm in the TEM₀₀ mode at a power output of 75 mW. Let the laser source 26 have a beam diameter and beam waste of 1.91 mm at the laser source 26 opening and a beam divergence of 0.00046 radians. The laser source 26 can be purchased from Jodon, Inc., 62 Enterprise Drive, Ann Arbor, Mich. 48103, using the part number 1508. The polarization of the beam B 44b is such that the direction of its electric field is perpendicular to the c-axis of the uniformly doped semiconductor 21. Let the distance between the laser source 26 and the uniformly doped semiconductor 21 be 1 m and let θ=5°. The temperature of the uniformly doped semiconductor 21 is 25° C.±5° C. If tₚ=24 hours then the doping superlattice composed of dopant layers orientated parallel to the semiconductor's polished surface 57 will be formed where Λ=129 nm±3 nm.

### EXAMPLE 5

For example 5 the optical configuration illustrated in FIG. 3A is used in air at 25° C. and 1 atm. Let the uniformly doped semiconductor 21 be a 1 mm thick, 10 mm diameter, polished wafer of single-crystalline wurtzite CdS where the c-axis is perpendicular to the wafer's polished surfaces. Let the uniformly doped semiconductor 21 have a front and back surface polish of 0.002 μm, a flatness of less than 15 μm, and a bow of less than 20 μm. Let the uniformly doped semiconductor 21 have an electron concentration of 2×10¹⁶ cm⁻³ in the conduction band at 25° C. Let the dopant 22 be Ag where Z=1×10¹⁵ Ag atoms/cm³. Let the laser source 26 be a constant wave, helium neon laser operating at 632.8 nm in the TEM₀₀ mode at a power output of 75 mW. Let the laser source 26 have a beam diameter and beam waste of 1.91 mm at the laser source 26 opening and a beam divergence of 0.00046 radians. The laser source 26 can be purchased from Jodon, Inc., 62 Enterprise Drive, Ann Arbor, Mich. 48103, using the part number 1508. The polarization of the beam B 44b is such that the direction of its electric field is perpendicular to the c-axis of the uniformly doped semiconductor 21. The polarization of the beam A 44a is such that the direction of its electric field is perpendicular to the c-axis of the uniformly doped semiconductor 21. Let the beam splitter 28 be a nonpolarizing cube beamsplitter designed for the laser wavelength 632.8 nm. Let the reflector A 29a and the reflector B 29b be square flat mirrors made from crown glass and coated with aluminum. The beam splitter 28, the reflector A 29a, and the reflector B 29b can be purchased from Melles Griot, 2051 Palomar Airport Road, 200, Carlsbad, Calif. 92009 using the part numbers 03 BSL 043 and 01 MFG 003. Let the distance between the laser source 26 and the beam splitter 28 be 1 m. Let the distance between the beam splitter 28 and the reflector B 29b be 1 m. Let the distance between the beam splitter 28 and the reflector A 29a be 1 m. Let θ=20°. The temperature of the uniformly doped semiconductor 21 is 25° C.±5° C. If tₚ=24 hours then the doping superlattice composed of dopant layers orientated parallel to the semiconductor's polished surface 57 will be formed where Λ=130 nm±3 nm.

### EXAMPLE 6

For example 6 the optical configuration illustrated in FIG. 4A is used in air at 25° C. and 1 atm Let the uniformly doped semiconductor 21 be a 1 mm thick, 10 mm diameter, polished wafer of single-crystalline wurtzite CdS where the c-axis is perpendicular to the wafer's polished surfaces. Let the uniformly doped semiconductor 21 have a front and back surface polish of 0.002 μm, a flatness of less than 15 μm, and a bow of less than 20 μm. Let the uniformly doped semiconductor 21 have an electron concentration of 2×10¹⁶ cm⁻³ in the conduction band at 25° C. Let the dopant 22 be Ag where Z=1×10¹⁵ Ag atoms/cm³. Let the laser source 26 be a constant wave, helium neon laser operating at 632.8 nm in the TEM₀₀ mode at a power output of 75 mW. Let the laser source 26 have a beam diameter and beam waste of 1.91 mm at the laser source 26 opening and a beam divergence of 0.00046 radians. The laser source 26 can be purchased from Jodon, Inc., 62 Enterprise Drive, Ann Arbor, Mich. 48103, using the part number 1508. The polarization of the beam B 44b is such that the direction of its electric field is perpendicular to the c-axis of the uniformly doped semiconductor 21. The polarization of the beam A 44a is such that the direction of its electric field is perpendicular to the c-axis of the uniformly doped semiconductor 21. Let the beam splitter 28 be a nonpolarizing cube beamsplitter designed for the laser wavelength 632.8 nm. Let the reflector A 29a be square flat mirror made from crown glass and coated with aluminum. The beam splitter 28 and the reflector A 29a can be purchased from Melles Griot, 2051 Palomar Airport Road, 200, Carlsbad, Calif. 92009 using the part numbers 03 BSL 043 and 01 MFG 003. Let the distance between the laser source 26 and the beam splitter 28 be 1 m. Let the distance between the beam splitter 28 and the reflector A 29a be 10 cm. Let θ=2°. The temperature of the uniformly doped semiconductor 21 is 25° C.±5° C. If tₚ=24 hours then the doping superlattice composed of dopant layers orientated perpendicular to the semiconductor's polished surface 58 will be formed where ψ=9 μm±0.2 μm.

Theory of Operation

While I believe the redistribution of the dopant 22 in the uniformly doped semiconductor 21 occurs because of a charge-state mechanism, I don't wish to be bound by this. The following two paragraphs is a description of the charge-state mechanism.

In the charge-state mechanism the diffusion rate of an atom in a solid is changed because of a change in the charge-state of the atom. Atoms in a solid are continuously gaining and losing energy from and to one another due to random, thermal fluctuations. Atoms tend to be restrained from moving throughout a solid because electric and magnetic fields emitted by neighboring atoms tend to hold them in place. The net charge, charge distribution, and size of an atom determines how strongly it is held in place by neighboring atoms. Occasionally an atom gains enough energy to overcome the restraining forces imposed on it by neighboring atoms and it diffuses to a new location in the solid. If an atom gains or loses an electron the atom's net charge, charge distribution, and size changes, thus the forces that tend to restrain the atom change as well. If the forces restraining the atom decrease, a increase in the frequency at which the atom gains enough energy to overcome the restraining forces imposed on it by neighboring atoms will result, thus it will diffuse to new locations in the solid more frequently. If the forces restraining the atom increase, a decrease in the frequency at which the atom gains enough energy to overcome the restraining forces imposed on it by neighboring atoms will result, thus it will diffuse to new locations in the solid less frequently.

In the present invention I believe that one or more of the valance electrons bonded to the dopants 22 are being excited to the uniformly doped semiconductor's 21 conduction band as a result of the absorption of photons from the laser beam A 44a and/or the laser beam B 44b. A short time after being ionized, the dopants 22 capture electrons, thus returning to their original charge state. During the period of time in which the dopants 22 have a missing valence electron, the forces restraining the dopant 22 decrease, thus an increase in the frequency at which the dopant 22 gains enough energy to overcome the restraining forces imposed on it by neighboring atoms results, and so it diffuses to new locations in the solid more frequently. The dopants 22 located in the high light intensity regions of the laser beam interference pattern are ionized at a greater rate than the dopants 22 located in the low light intensity regions of the laser beam interference pattern, thus the net flux of dopant 22 movement is towards the low light intensity regions of the laser beam interference pattern. Over time the dopants 22 accumulate in the low light intensity regions of the laser beam interference pattern, thus forming the layer composed of a high dopant density 59 and the layer composed of a low dopant density 60.

### CONCLUSIONS, RAMIFICATIONS, AND SCOPE

Accordingly, the reader will see that the method for forming a doping superlattice using a laser of this invention can be used to form a variety of one, two, and three-dimensional doping superlattices. Forming each dopant layer of a doping superlattice simultaneously is more time efficient than forming it one layer at a time. In addition, using the method of this invention results in the formation of a doping superlattice in a semiconductor or insulator where the doping superlattice period or spacing is constant. Furthermore, the doping superlattice formed by the method of this invention is changeable during the use of or after using the doping superlattice.

While the above description contains many specificities, these should not be construed as limitations on the scope of the invention, but rather as an exemplification of one preferred embodiment thereof. Many other variations are possible. For example:
The CdS wafer uniformly doped with Cu or Ag can be another type of semiconductor doped with other types of dopants with different dopant densities. However, changing the semiconductor and dopant changes the required laser wavelength because each dopant has specific ionization energies. There are numerous semiconductors, insulators, and dopants, and dopant densities that can be used for the formation of a doping superlattice using the method of this invention.
The uniformly doped semiconductor does not have to be a monocrystal. The uniformly doped semiconductor can be amorphous or polycrystalline, however the best quality doping superlattice is achieved if the uniformly doped semiconductor is a monocrystal.
The thickness of the semiconductor is not restricted to 1 mm. The lower the absorption coefficient of the uniformly doped semiconductor, the greater the semiconductor thickness can be without significantly reducing intensity of the beam A, beam B, and the laser beam interference pattern.
The wafer diameter does not have to be 10 mm. However, diameters that are too small can cause unwanted diffraction effects that adversely effect the quality of the doping superlattice.
The temperature of the uniformly doped semiconductor does not have to be is 25° C.±5° C. Conducting the method of this invention on a uniformly doped semiconductor at an elevated temperature will increase the solubility of the dopant in the uniformly doped semiconductor, thus a greater variation of the dopant density between the dopant layers can be achieved in the doping superlattice.
The dopant does not have to be uniformly distributed in the semiconductor if a anisotropic doping superlattice is desired or a doping superlattice is desired in only selected regions of the semiconductor.
The laser source does not have to be a He—Ne laser. Any coherent light source that can provide the required laser wavelength and sufficient power can be used.
The mode of the laser source does not have to be TEM₀₀. Other laser source modes will produce more complex laser beam interference patterns, thus result in more complex shaped and patterned doping superlattices.
If the electric field of beam A and/or beam B is not perpendicular to the wafer's c-axis then two interference patterns will result and overlap one another due to the birefringence of CdS, thus a more complex shaped and patterned doping superlattice will be formed.
The polarization of the laser source and/or the laser beam A and/or laser beam B, can be different than the laser source polarization used in the method of this invention. Whatever polarization is used, the resultant laser beam interference pattern determines the shape and pattern of doping superlattice.
A pulsed laser source can be used instead of the constant wave laser source for the FIG. 2A configuration if the pulse width is much greater than the wafer thickness.
A pulsed laser source can be used instead of the constant wave laser source for the FIG. 3A configuration if the optical path length for beam A is equal to the optical path length for beam B and the pulse width is much greater than the wafer thickness.
A pulsed laser source can be used instead of the constant wave laser source for the FIG. 4A configuration if the optical path length for beam A is equal to the optical path length for beam B.
The shape of the reflector A and reflector B, the shape of the beam A and beam B wave fronts, and the shape of the surfaces of the uniformly doped semiconductor are not limited to flat surfaces if a curved or uniquely shaped doping superlattice is desired. Whatever the component shapes used in the method of this invention, the resultant laser beam interference pattern determines the shape and pattern of the doping superlattice.
Reflector A and reflector B can be any optical component that can control the direction of beam A and beam B, respectively, for example retroreflectors.
More than one laser, and/or beamsplitters, and/or reflectors, and/or other optical components may be used to create a complex structured doping superlattice. Whatever number of components used, the resultant laser beam interference pattern determines the shape and pattern of doping superlattice.
If CdS and Cu or Ag is not used for the semiconductor and dopant, respectively, a new laser source may be required which would then require a new non-polarizing beam splitter that is designed for the new laser source wavelength.
If a polarizing beam splitter is used then additional optical components will be needed to align the polarization's of beam A and beam B.
The quality of the doping superlattice can be improved if the method of this invention is conducted in a vacuum instead of air. The vacuum will eliminate air turbulence that tends to distort the laser beam wave fronts.
tₚ can be less than or greater than 24 hours, however the greater the value of tₚ, the higher the quality the doping superlattice will be.
The uniformly doped semiconductor can be doped with several types of dopant so that several overlapping, doping superlattices can be formed in the same wafer. Each dopant would have its own solubility limit or ionization energy in the uniformly doped semiconductor so each doping superlattice could be formed at a particular temperature and/or laser wavelength. In the case of solubility: the least soluble dopant would be formed into a doping superlattice first at a high temperature and the highest soluble dopant would be formed into a doping superlattice last at a low temperature. In the case of ionization energy: the dopant with the highest ionization energy would be formed into a doping superlattice first at a high-energy wavelength and the dopant with the lowest ionization energy would be formed into a doping superlattice last at a low-energy wavelength
The geometry of the regions composed of a high dopant density in a doping superlattice is not limited to layers, lines or wires, and dots or clusters. Other geometry's are possible using various optical configurations. A few potential geometry's are circles, spheres, cylinders, all five of the two-dimensional Bravais lattices, and all fourteen of the three-dimensional Bravais lattices.
Instead of enhancing the dopant diffusion in the laser beam interference regions of high light intensity, it is possible for some semiconductors and dopants that the opposite effect will occur where the dopant diffusion is decreased in the laser beam interference regions of high light intensity.
In the method of this invention the uniformly doped semiconductor is located on the outside of the laser. A laser beam interference pattern exists inside the laser's resonant cavity, thus the uniformly doped semiconductor can be transformed into a doping superlattice be placing it inside the laser's resonant cavity if the wafer is not too thick. Placing the uniformly doped semiconductor inside the laser's resonant cavity eliminates the need for additional optical components.

Accordingly, the scope of the invention should be determined not by the embodiments illustrated, but by the appended claims and their legal equivalents.

1. A method for converting a solid into a doping superlattice, comprising the step of:
a. establishing a light interference pattern in said solid for a predetermined amount of time.

2. The method of claim 1 wherein said doping superlattice is composed of a dopant density that is a periodic function of position in said solid.

3. The method of claim 1 wherein said doping superlattice is composed of a plurality of dopant layers.

4. The method of claim 1 wherein said doping superlattice is composed of a two-dimensional array of dopant lines or dopant wires.

5. The method of claim 1 wherein said doping superlattice is composed of a three-dimensional array of dopant dots or dopant clusters.

6. The method of claim 1 wherein said solid is a semiconductor.

7. The method of claim 1 wherein said solid is a insulator.

8. The method of claim 1 wherein said light interference pattern is composed of a laser beam interference pattern.

9. A method for converting a solid into a doping superlattice, comprising the step of:
a. intersecting a plurality of laser beams in said solid for a predetermined amount of time.

10. The method of claim 9 wherein said doping superlattice is composed of a dopant density that is a periodic function of position in said solid.

11. The method of claim 9 wherein said doping superlattice is composed of a plurality of dopant layers.

12. The method of claim 9 wherein said doping superlattice is composed of a two-dimensional array of dopant lines or dopant wires.

13. The method of claim 9 wherein said doping superlattice is composed of a three-dimensional array of dopant dots or dopant clusters.

14. The method of claim 9 wherein said solid is a semiconductor.

15. The method of claim 9 wherein said solid is a insulator.

16. A method for forming a periodic distribution of impurities in a solid, comprising the step of:
a. establishing a light interference pattern in said solid for a predetermined amount of time.

17. The method of claim 16 wherein said periodic distribution of impurities is composed of a plurality of dopant layers.

18. The method of claim 16 wherein said periodic distribution of impurities is composed of a two-dimensional array of dopant lines or dopant wires.

19. The method of claim 16 wherein said periodic distribution of impurities is composed of a three-dimensional array of dopant dots or dopant clusters.

20. The method of claim 16 wherein said solid is a semiconductor.

21. The method of claim 16 wherein said solid is a insulator.

22. The method of claim 16 wherein said light interference pattern is composed of a laser beam interference pattern.

23. The method of claim 1 wherein said light interference pattern is established using a beamsplitter and a reflector.

24. The method of claim 9 wherein said plurality of laser beams are intersected using a beamsplitter and a reflector.

25. The method of claim 16 wherein said light interference pattern is established using a beamsplitter and a reflector.

26. The method of claim 1 wherein said light interference pattern is established using a beamsplitter and two reflectors.

27. The method of claim 9 wherein said plurality of laser beams are intersected using a beamsplitter and two reflectors.

28. The method of claim 16 wherein said light interference pattern is established using a beamsplitter and two reflectors.
